(19) United States
(12) Patent Application Publication
(10) Pub. No.: US 2019/0187368 A1
(43) Pub. Date: Jun. 20, 2019

(54) METHOD FOR FABRICATING BROADBAND NEAR INFRARED PLASMONIC WAVEGUIDE

(71) Applicant: KOREA INSTITUTE OF SCIENCE AND TECHNOLOGY, Seoul (KR)

(72) Inventors: Seok Joon KWON, Seoul (KR); Hyoung Uk KIM, Seoul (KR); IL KI HAN, Seoul (KR); KWAN IL LEE, Seoul (KR); Seonju YEO, Seoul (KR)

(73) Assignee: KOREA INSTITUTE OF SCIENCE AND TECHNOLOGY, Seoul (KR)

(21) Appl. No.: 16/216,250

(22) Filed: Dec. 11, 2018

(30) Foreign Application Priority Data
Dec. 12, 2017 (KR) 10-2017-0170015

(51) Int. Cl. G02B 6/10; G03F 7/16; G03F 7/20; G03F 7/32; G03F 7/40

(52) U.S. Cl. CPC G02B 6/102; G03F 7/162; G03F 7/168; G03F 7/40; G03F 7/322; G03F 7/32; G03F 7/2002

(57) ABSTRACT

In a method for fabricating a broadband near infrared plasmonic waveguide, the method includes forming a first pattern on a substrate. A metal thin film is evaporated on the substrate on which the first pattern is formed. The first pattern is removed from the substrate on which the metal thin film is evaporated, to remain a second pattern on the substrate on which the metal thin film is evaporated. The substrate on which the second pattern is formed is heated, to induce dewetting, so that metal nano particles are formed on the substrate.

### PRIORITY STATEMENT

This application claims priority under 35 U.S.C. § 119 to Korean Patent Application No. 10-2017-0170015, filed on Dec. 12, 2017 in the Korean Intellectual Property Office (KIPO), the contents of which are herein incorporated by reference in their entireties.

### BACKGROUND

### 1. Field of Disclosure

The present disclosure of invention relates a method for fabricating a broadband near infrared plasmonic waveguide minimizing a signal loss and transmitting a surface electric field signal with a relatively small scale, for controlling localized surface plasmon resonance (LSPR) generated in an intersurface between a metal nano particle and a dielectric, and a transmitting distance of an electric field signal transmitted along the intersurface.

### 2. Description of Related Technology

For next generation light information processer and quantum information processing apparatus technologies, the light source which is to be a target is controlled to be a predetermined distance in a micrometer scale.

Thus, in a plasmonic structure in which dielectric and metal nano particle are combined with each other, surface plasmon polariton (SPP) is formed on an intersurface of the metal-dielectric, and then a radio wave of the surface plasmon polariton may be controlled along a horizontal direction.

For the control of the radio wave of the surface plasmon polariton along the horizontal direction, conventionally, the metal nano particles are periodically arranged in two dimension to form a diffraction grid, a width of a meal thin film is controlled to form a thin-film optical waveguide, or a period or a direction of a pattern are diversified to control near-field.

Here, a size less than about 1 μm should be formed with a relatively large size more correctly, so that electron-beam lithography is used for a precise control, generally.

However, a manufacturing cost is relatively increased, an error in manufacturing the structure affects precision of the control, and the structure once formed is effective in a predetermined waveband.

Recently, non-periodic two dimensional metal nano particle arrangement is formed, and the near field is formed for the broadband incident light wavelength.

Korean patent No. 10-1533233 discloses that the optical waveguide using the conventional periodic two dimensional metal nano particle arrangement focuses a predetermined wavelength band to control the surface plasmon polariton and the near-field, and in the non-periodic metal nano particle arrangement, the broadband incident wavelength may be controlled. However, in the non-periodic metal nano particle arrangement, the period is totally disappeared so that the signal loss may be increased in transmitting the surface plasmon polariton electromagnetic wave.

Thus, to minimize the signal loss, to control near-infrared ray broadband incident light corresponding to a communication band or a light information processing band on the surface, and to control a distance of the transmitting, entirely periodic metal nano particle arrangement or entirely non-periodic metal nano particle arrangement is not proper, and a system having intermediate characteristics between the above two arrangements is required.

Regarded prior arts on the technologies mentioned above are Korean patents No. 10-1533233 and No. 10-1578614.

### SUMMARY

The present invention is developed to solve the above-mentioned problems of the related arts.

The present invention provides a method for fabricating a broadband near infrared plasmonic waveguide capable of minimizing a signal loss and transmitting a surface electric field signal with a relatively small scale, for controlling localized surface plasmon resonance (LSPR) generated in an intersurface between a metal nano particle and a dielectric, and a transmitting distance of an electric field signal transmitted along the intersurface.

According to an example embodiment, the method includes forming a first pattern on a substrate. A metal thin film is evaporated on the substrate on which the first pattern is formed. The first pattern is removed from the substrate on which the metal thin film is evaporated, to remain a second pattern on the substrate on which the metal thin film is evaporated. The substrate on which the second pattern is formed is heated, to induce dewetting, so that metal nano particles are formed on the substrate.

In an example embodiment, the forming the first pattern on the substrate may include coating a photoresist on the substrate, hardening the photoresist coated on the substrate, partially exposing the hardened photoresist firstly using a mask, to form the first pattern, hardening the first pattern and the photoresist, with removing the mask, exposing the first pattern and the photoresist secondly, and removing the photoresist which is not exposed to a light from the substrate due to the mask in the exposing firstly.

In an example embodiment, in the coating the photoresist on the substrate, a first solution and the photoresist may be sequentially coated on the substrate, and then a spin coating may be performed.

In an example embodiment, the first solution may be a methoxy-propyl acetate solution.

In an example embodiment, between the coating the photoresist on the substrate and the hardening the photoresist, a side area of the coated photoresist may be removed using acetone.

In an example embodiment, in the forming the first pattern, UV light having a wavelength between about 350 nm and about 450 nm may be used for the exposing.

In an example embodiment, in the removing the photoresist from the substrate, the photoresist may be removed from the substrate using a developing solution of tetramethylammonium hydroxide, and then the photoresist remained in the substrate may be additionally removed using a deionized water.

In an example embodiment, in the removing the first pattern, the first pattern may be removed using an ultrasonic wave generator.

In an example embodiment, the metal thin film may be melted to be arranged non-periodically, so that the metal nano particles may be formed.

In an example embodiment, in the forming the metal nano particles, a heated tube electric furnace or a heated plate may be used for the heating.

In an example embodiment, sizes of the metal nano particles and distances between the metal nano particles, may be controlled by a heating time, a thickness of the metal thin film and a surface state of the substrate.

In an example embodiment, each of the metal nano particles may have a radius less than about 300 nm.

In an example embodiment, the metal thin film may be formed from one of silver, gold, platinum, aluminum, iron, zinc, copper, tin, bronze, brass and nickel.

According to the present example embodiments, metal nano particle arrangement having randomness may be performed with a relatively large size and a relatively simple process from a metal thin film, using solid dewetting.

Here, half-non periodic metal nano particle arrangement may be formed in addition to periodic metal nano particle arrangement at the same time, using the conventional photo lithographic process. Here, a thickness of the metal thin film, a temperature of heat treatment, a processing time, and so on may be controlled, to control a size or a distance between the metal nano particles effectively, so that metal nano particle arrangement may be properly formed.

By forming an optical waveguide as mentioned above, a loss of the near infrared ray broadband incident light may be minimized by a relatively long distance (maximum distance is about 120 μm along a direction parallel with the metal-dielectric intersurface (signal loss with respect to the near infrared ray light signal with a range of 1,200˜1,600 nm is less than 3.8 dB 100 μm⁻¹, such that the near infrared ray broadband incident light may be transmitted.

In addition, near infrared short wavelength incident signal which is used for a communication band may be stably transmitted along a surface.

In addition, a transmitting distance of near infrared broadband incident light which is used for a chemical sensor or a spectroscope may be differentiated or a transmitting efficiency thereof may be differentiate, so that the planer spectrum effect may be increased.

### BRIEF DESCRIPTION OF THE DRAWINGS

FIG. 1 is a flow chart illustrating a method for fabricating a broadband near infrared plasmonic waveguide according to an example embodiment of the present invention;

FIG. 2 is a flow chart illustrating forming a first pattern on a substrate in the method of FIG. 1;

FIGS. 3A, 3B, 3C, 3D, 3E, 3F, 3G, 3H and 31 are process views illustrating the method of FIG. 1;

FIG. 4 is a cross-sectional view illustrating a first pattern formed through an exposing process in the method of FIG. 1;

FIG. 5A is a process view illustrating the first pattern having a negative resist in the method of FIG. 1 and, FIG. 5B is a process view illustrating the first pattern having a positive resist in the method of FIG. 1;

FIGS. 6A and 6B are images illustrating the first pattern formed in the process of FIG. 3F;

FIG. 6C is an image illustrating a second pattern formed in the process of FIG. 3H;

FIG. 6D is an image illustrating half-non periodic metal nano particles formed in the process of FIG. 31; and

FIGS. 7A, 7B and 7C, FIGS. 8A, 8B and 8C, FIG. 9, and FIGS. 10A and 10B are images or graphs illustrating an effect of the waveguide formed in the method of FIG. 1 having improved signal transmitting efficiency.

### DETAILED DESCRIPTION

The invention is described more fully hereinafter with Reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity. It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

The terminology used herein is for the purpose of describing particular embodiments only and is not intended to be limiting of the invention. As used herein, the singular forms “a,” “an” and “the” are intended to include the plural forms as well, unless the context clearly indicates otherwise.

It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, exemplary embodiment of the invention will be explained in detail with reference to the accompanying drawings.

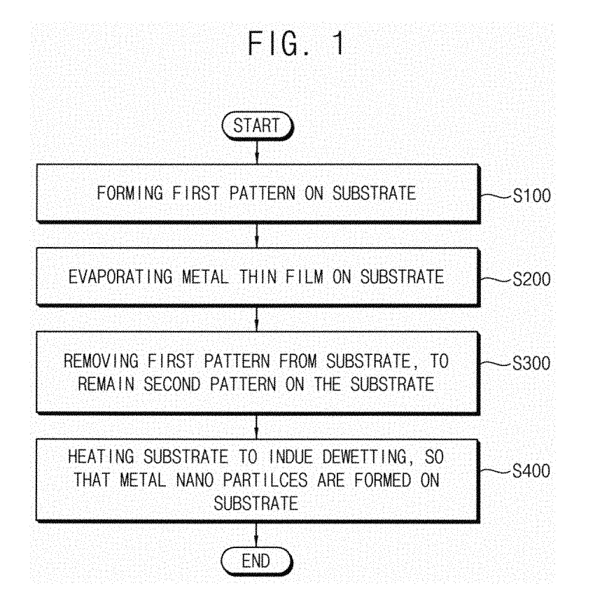

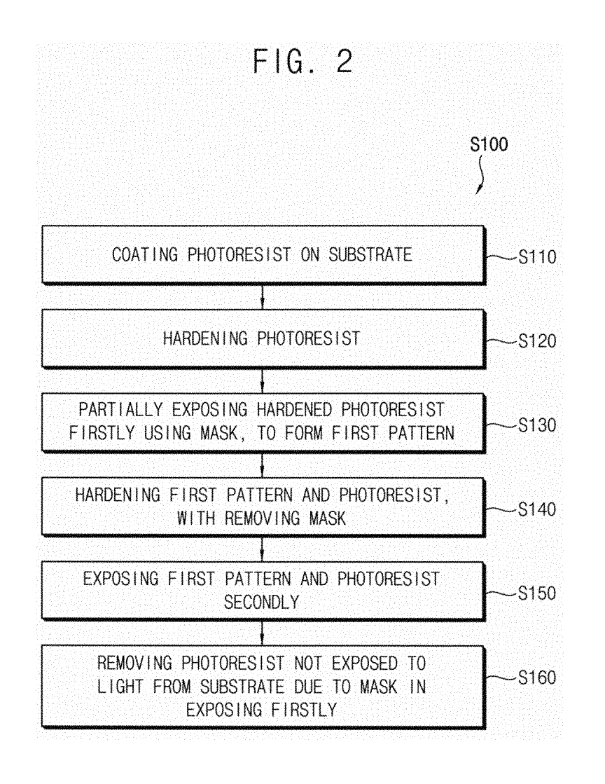

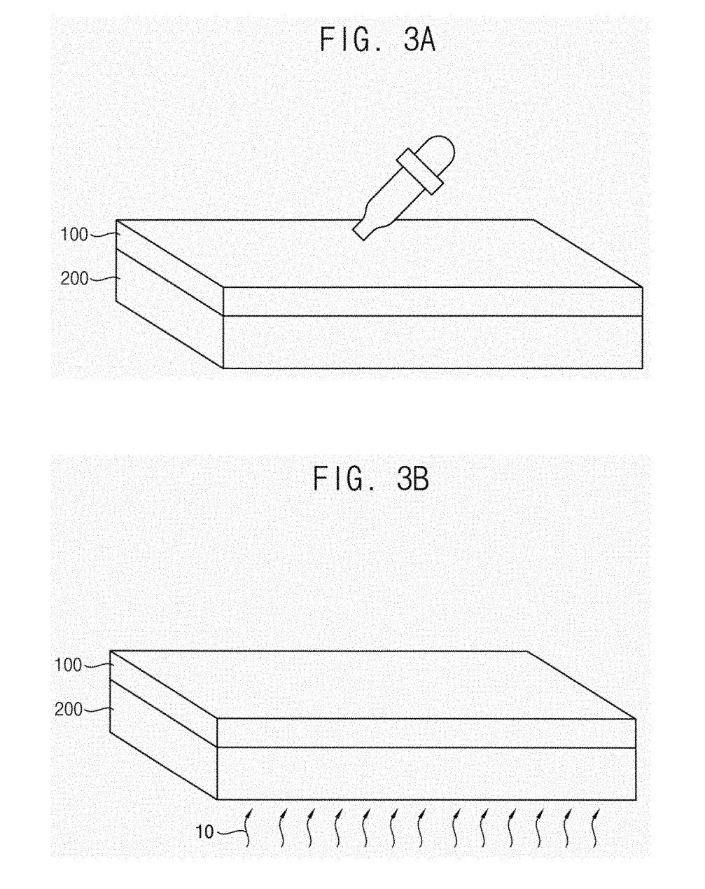

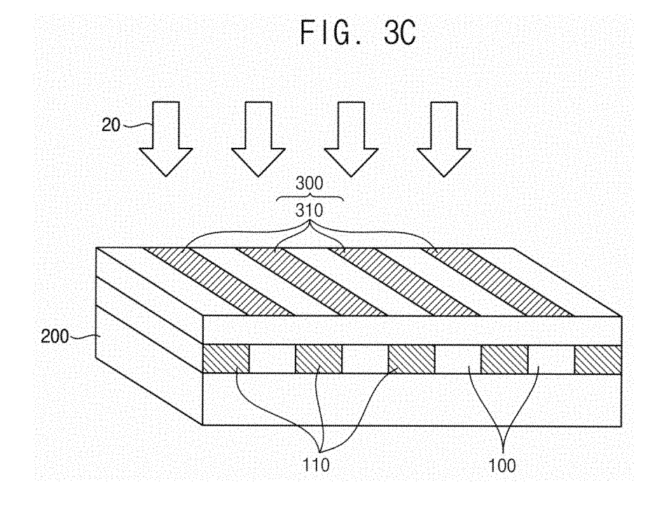

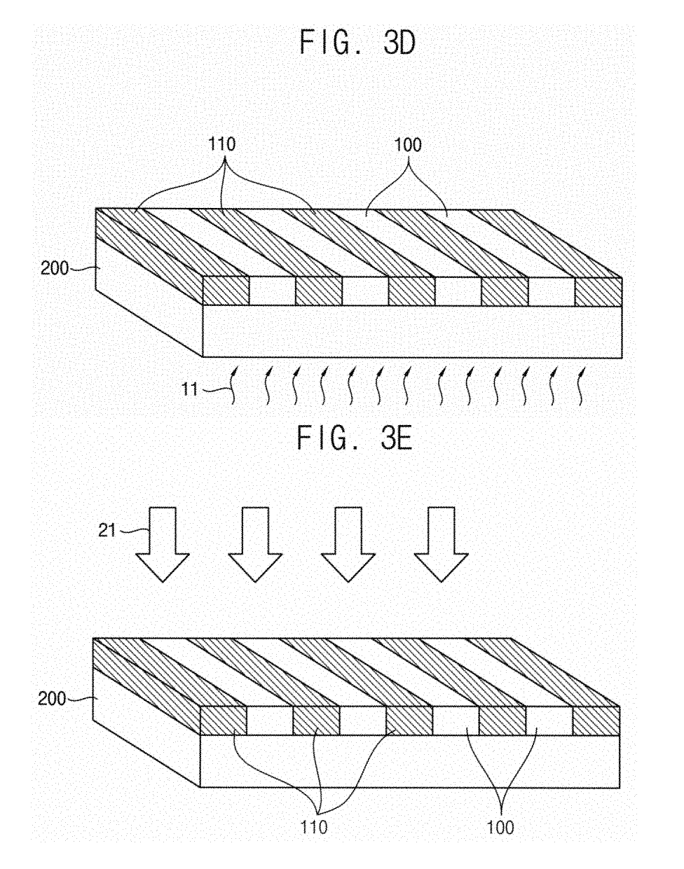

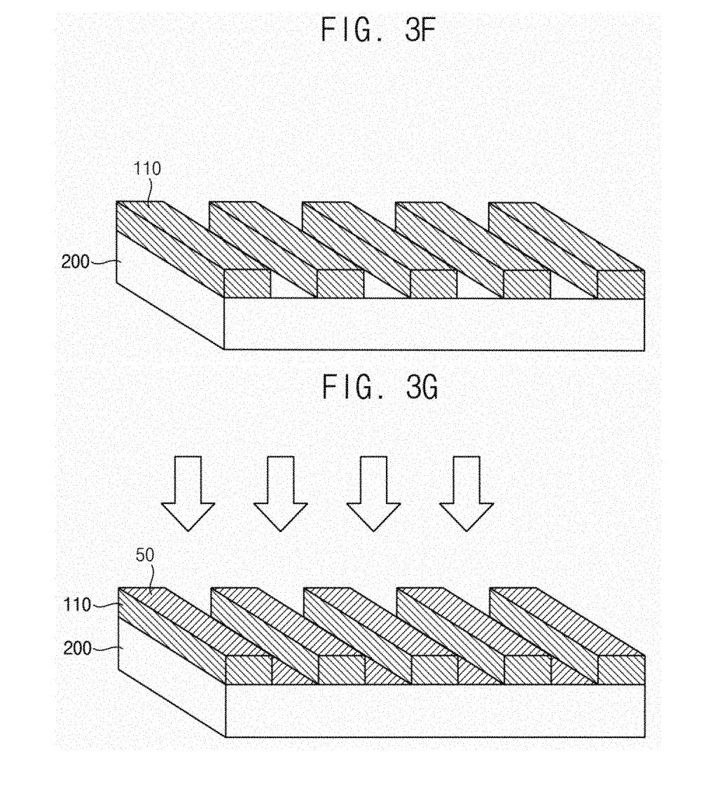

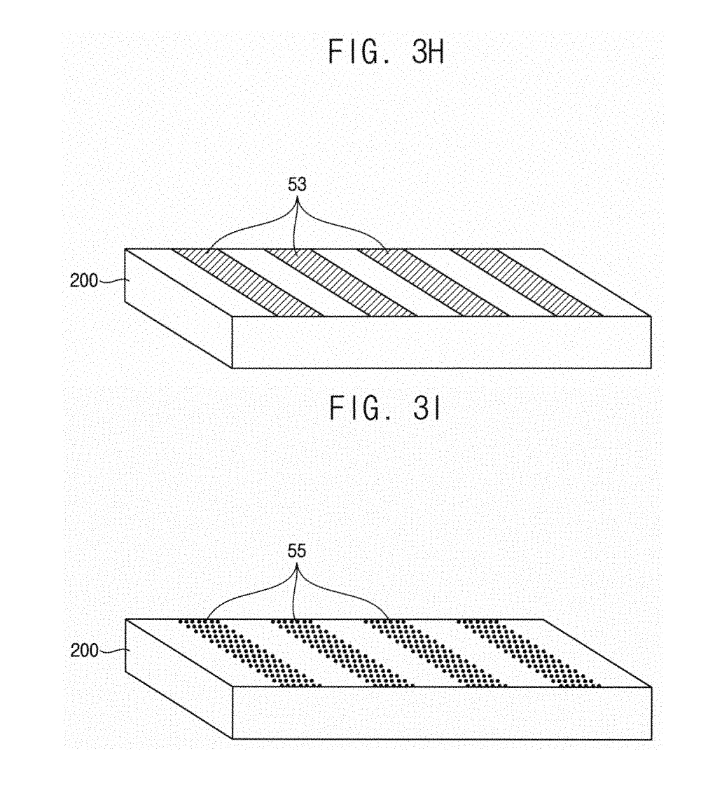

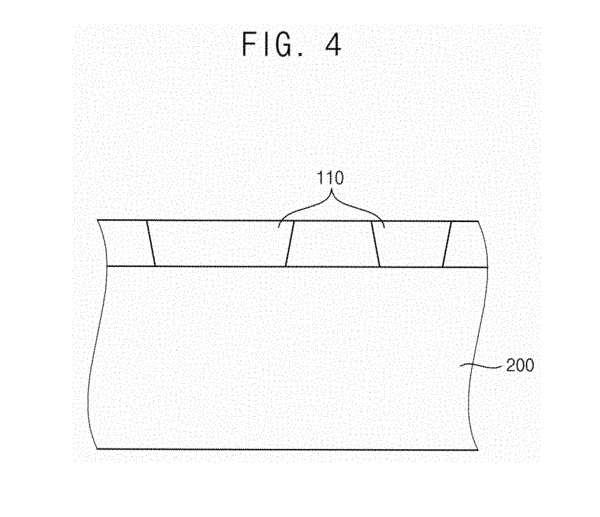

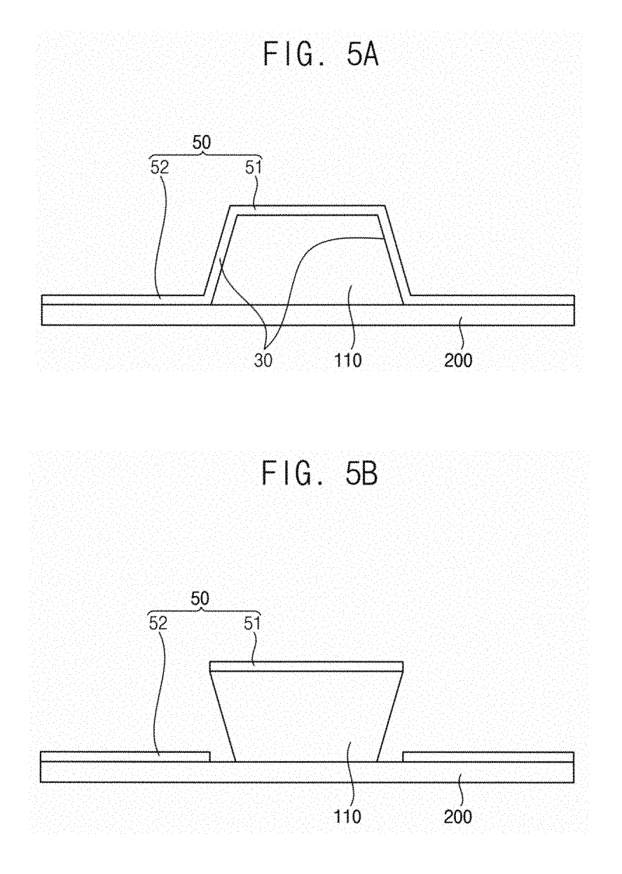

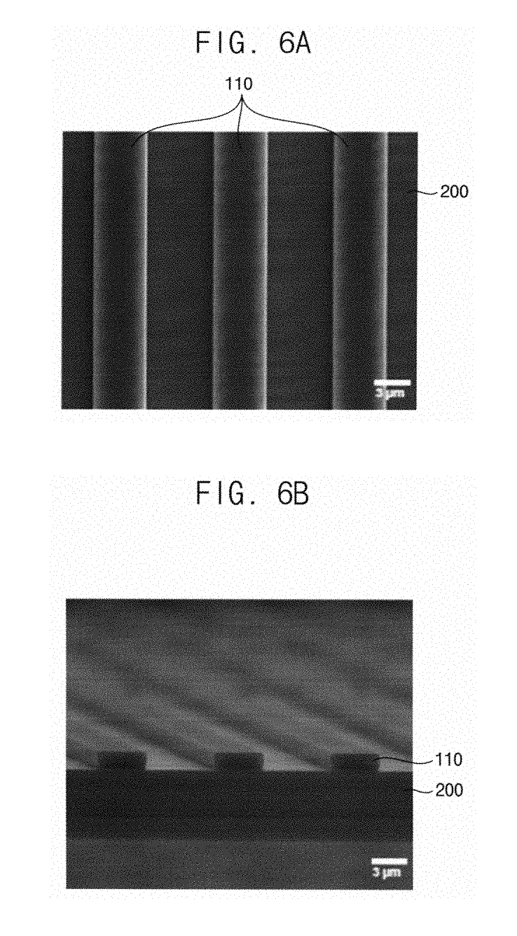

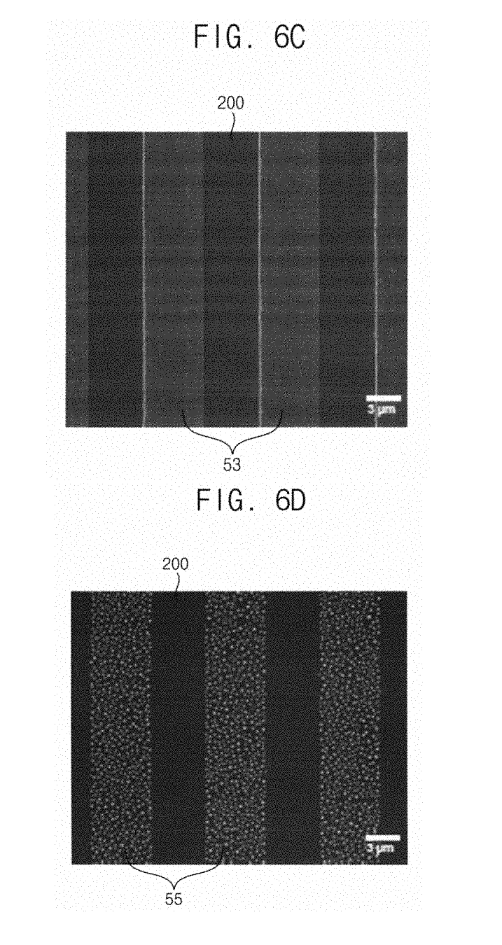

FIG. 1 is a flow chart illustrating a method for fabricating a broadband near infrared plasmonic waveguide according to an example embodiment of the present invention. FIG. 2 is a flow chart illustrating forming a first pattern on a substrate in the method of FIG. 1. FIGS. 3A, 3B, 3C, 3D, 3E, 3F, 3G, 3H and 31 are process views illustrating the method of FIG. 1. FIG. 4 is a cross-sectional view illustrating a first pattern formed through an exposing process in the method of FIG. 1. FIG. 5A is a process view illustrating the first pattern having a negative resist in the method of FIG. 1 and, FIG. 5B is a process view illustrating the first pattern having a positive resist in the method of FIG. 1. FIGS. 6A and 6B are images illustrating the first pattern formed in the process of FIG. 3F. FIG. 6C is an image illustrating a second pattern formed in the process of FIG. 3H. FIG. 6D is an image illustrating half-non periodic metal nano particles formed in the process of FIG. 31.

Referring to FIGS. 1, 2 and 3A, in the method for fabricating a broadband near infrared plasmonic waveguide, firstly, a first pattern is formed on a substrate 200.

A photoresist 100 is coated on the substrate 200, to form the first pattern on the substrate 200 (step S110). Here, as illustrated in FIG. 3A, the photoresist 100 is once provided for the coating on the substrate 200, by a predetermined amount.

Although not shown in the figure, a first solution may be used for uniformly coating the photoresist 100 on the substrate 200.

For example, the first solution is coated on the substrate 200, and then the photoresist is coated on the substrate 200. Then, a spin coater is used for spin coating the first solution and the photoresist 100 at the same time, so that the photoresist 100 may be coated on the substrate 200 more uniformly.

Here, the first solution may be a methoxy-propyl acetate solution.

A thickness of the photoresist coated on the substrate 200 may be controlled by a rotational speed of the spin coater, and then the thickness of the photoresist 100 may affect the conditions for forming the first pattern mentioned below.

As the rotational speed of the spin coater increases, a side area of the photoresist coated on the substrate 200 becomes thicker than a central area thereof, and thus the first pattern may be less uniformed.

Thus, in the present example embodiment, acetone is used for removing the side area of the photoresist thicker than the central area thereof, so that a thickness of the side area may be substantially same as that of the central area.

Then, referring to FIGS. 1, 2 and 3B, the photoresist 100 coated on the substrate 200 is hardened (step S120). Here, although not shown in the figure, a heat 10 generated from a heater disposed under the substrate 200 is provided to the substrate 200, so that the photoresist 100 may be hardened.

For example, the heater is disposed under the substrate 200, and then the heat is provided to the substrate 200, to harden the photoresist 100 firstly. Alternatively, the heater may be disposed over the substrate 200 and then the heat may be provided to the substrate. In addition, the substrate 200 may be disposed inside of a chamber providing the heat to the substrate.

Then, referring to FIGS. 1, 2 and 3C, a mask 300 having an arrangement pattern 310 is disposed on the hardened photoresist 100, and a light 20 is provided to the mask, for a first exposing process (step S130). Here, during the first exposing process, portions or areas not blocked by the mask 300 are exposed such that the photoresist 100 is remained, and portions or areas blocked by the mask 300 are not exposed such that the first pattern 110 is formed.

Here, the light 20 used for the first exposing process may be UV light having a wavelength between about 350 nm and about 450 nm.

Then, referring to FIGS. 1, 2 and 3D, the mask 300 is removed from the substrate 200, and then the first pattern 110 formed on the substrate 200 via the first exposing process and the photoresist not exposed in the first exposing process are additionally hardened (step S140).

Here, as mentioned above, the heater (not shown) disposed under the substrate 200 provides the heat for the hardening of the first pattern 110 and the photoresist 100. Alternatively, the heater may be disposed over the substrate 200, or the substrate 200 may be disposed inside of the heating chamber.

Then, referring to FIGS. 1, 2 and 3E, after hardening the first pattern 110 and the photoresist 100, the light 21 is provided to the substrate 200 for a second exposing process (step S150).

Here, the first pattern 110 may be a negative resist. Thus, as illustrated in FIG. 4, the first pattern 110 may have a cross-sectional shape of reversed-trapezoid due to the second exposing process. Accordingly, the first pattern 110 has the reversed-trapezoid shape, so that the first pattern 110 may be removed more easily in the following processes of evaporating a metal thin film 50 on the first pattern 110 and removing the first pattern 110, and a second pattern may be formed more easily.

Referring to FIG. 5A, when the first pattern 110 is a positive resist, the metal thin film 50 is formed on an inclined surface 30 of the first pattern 110 when the metal is vertically evaporated on the first pattern 110. Then, in the following lift-off process, a portion 51 of the metal thin film 50 which would be removed is connected to a portion of the metal film 52 which should be remained. Thus, the portion 52 of the metal film which should be remained may be removed or damaged in removing the first pattern 110, or the portion 51 of the metal film which would be removed may be remained or the first pattern 110 may be only removed.

Alternatively, when the first pattern 110 is a negative resist, as illustrated in FIG. 5B, the portion 51 of the metal thin film which would be removed is disconnected with the portion 52 of the metal thin film which should be remained, when the metal thin film 50 is evaporated on the first pattern 110. Thus, the portion 51 which would be removed may be only removed without damaging or removing the portion 52 which should be remained.

After the second exposing process, as illustrated in FIGS. 1, 2 and 3F, the photoresist 100 not exposed to the light due to the mask 300 in the first exposing process, is removed from the substrate 200 (step S160).

Then, as illustrated in FIGS. 6A and 6B, the first pattern 110 is only remained on the substrate 200.

Here, a developing solution of tetramethylammonium hydroxide is used to remove the photoresist 100 from the substrate 200, and then the photoresist 100 remained on the substrate 200 is cleaned using a deionized water. Thus, the photoresist 100 is entirely removed.

Then, referring to FIGS. 1 and 3G, the metal thin film 50 is evaporated on the substrate 200 on which the first pattern 110 is formed (step S200). Here, as explained referring to FIG. 4B, the metal thin film 50 is evaporated on the first pattern 110 and the substrate 200.

A thermal evaporator may be used for the evaporating process, and alternatively, electron beam evaporation, sputtering evaporation, and so on may be used for the evaporating process.

Here, the metal thin film 50 may include silver.

Then, referring to FIGS. 1 and 3H, the first pattern 110 is removed from the substrate 200 on which the metal thin film 50 is evaporated (step S300). Here, an ultrasonic wave generator may be used for the removing of the first pattern 110 from the substrate 200 (lift-off process).

Then, on the substrate 200, as illustrated in FIG. 6C, a second pattern 53 in which the metal thin film 50 is evaporated is only remained.

Finally, referring to FIGS. 1 and 31, a heat treatment process is performed on the substrate 200 on which the second pattern 53 is formed, to induce dewetting. Then, as illustrated in FIG. 6D, the second pattern 53 including the metal thin film 50 is formed as half-non periodic metal nano particles 55, due to the dewetting (step S400).

Here, the metal nano particles 55 may be arranged inside of the second pattern 53, randomly.

Accordingly, the metal nano particles 55 are entirely arranged as the second pattern 53, and then the metal nano particles 55 may have a predetermined pattern on the substrate, so that the metal nano particles 55 may form a periodic pattern. However, the metal nano particles 55 are arranged randomly inside of the second pattern 53, and thus may be defined to have a non-periodic pattern.

Thus, the metal nano particles 55 formed via the method according to the present example embodiment, may be defined to have a half (or semi)-non periodic (or, half (or semi)-periodic) pattern.

For the heat treatment process inducing the dewetting, a tube electric furnace or a heating plate heated between about 300° C. and about 500° C. may be used, to melt the metal thin film. Alternatively, the heater providing the heat or the laser irradiating the heat which melts the metal thin film may be used for the heat treatment process inducing the dewetting.

Further, as the metal thin film 50, one of silver, gold, platinum, aluminum, iron, zinc, copper, tin, bronze, brass and nickel may be used. Here, the metal thin film forming processes or heat treatment process may be properly selected, considering the materials included in the metal thin film 50, and further the conditions for the heat treatment may be properly selected, considering the materials included in the metal thin film 50.

Each of the half-non periodic metal nano particles 55 formed due to the dewetting may have a radius less than about 300 nm.

The size of each of the half-non periodic metal nano particles 55, and the distances between the half-non periodic metal nano particles 55 may be properly controlled by controlling the heating time for the substrate 200, the thickness of the metal thin film 50, and a surface state of the substrate 200.

Accordingly, the metal nano particles 55 may be formed half-non periodically, as illustrated in FIG. 6D.

In addition, an optical waveguide in which the half-non periodic metal nano particles are arranged variously may be fabricated using the half-non periodic metal nano particles, and hereinafter, the experimental results for a signal transmitting efficiency of the optical waveguide are explained.

The optical waveguide may be formed via the non-periodic metal nano particles. Alternatively, the non-periodically arranged metal nano particles 55 are formed to have a predetermined pattern on the substrate, such that the optical waveguide may be formed via the half-non periodic metal nano particles (for example, a second pattern in which the non-periodic metal nano particles are formed, and a portion in which the non-periodic metal nano particles are not formed, are repeated).

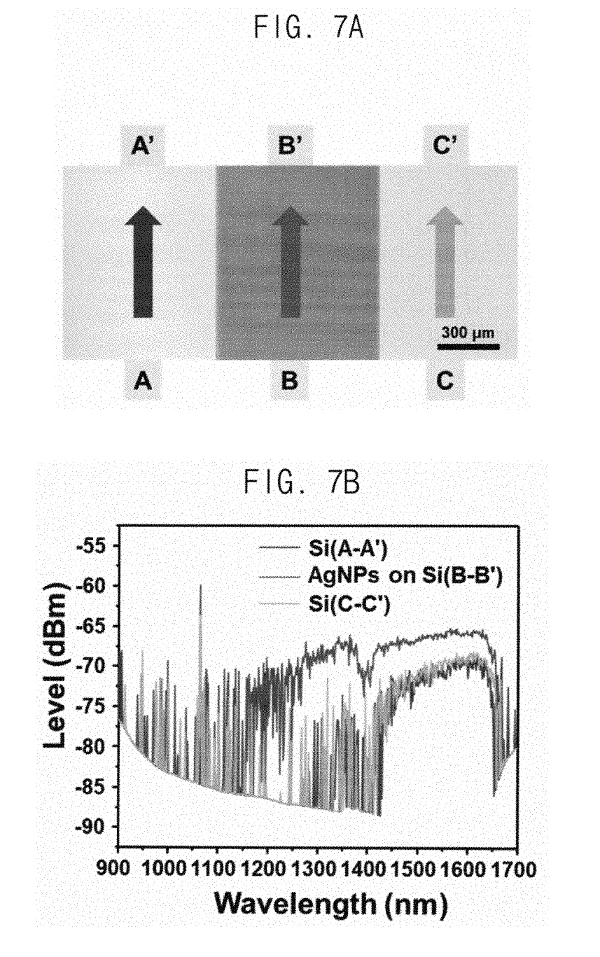

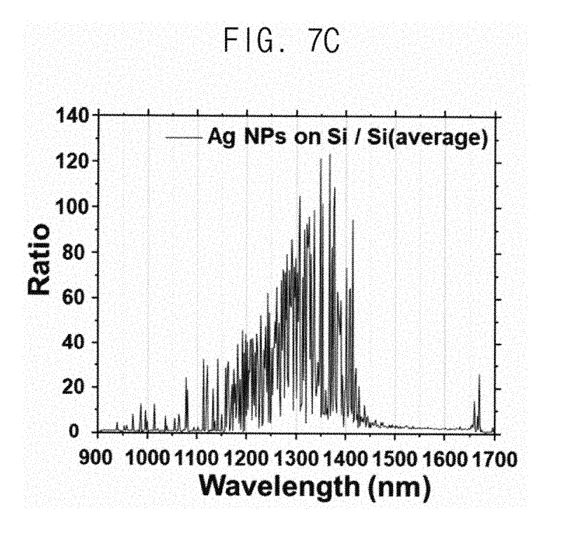

FIGS. 7A, 7B and 7C, FIGS. 8A, 8B and 8C, FIG. 9, and FIGS. 10A and 10B are images or graphs illustrating an effect of the waveguide formed in the method of FIG. 1 having improved signal transmitting efficiency.

In FIG. 7A, the substrate having divided areas are illustrated. Referring to FIG. 7A, an intensity of the signal passing through areas of a silicon (Si) substrate (A->A′, C->C′), and an intensity of the signal passing through an area of half non-periodic silver nano particle arrangement (B->B′), are shown.

Referring to FIG. 7B, when passing the area of half non-periodic silver nano particle arrangement, the signal is transmitted better at a range between 1,100 nm and 1,700 nm, than when the signal passes through the areas of the silicon substrate.

FIG. 7C show that a power ratio of the half non-periodic metal(silver) nano particles with respect to the silicon substrate. Here, a level value dBm is changed to a power value mW.

Referring to FIG. 7C, the signal transmitting may be increased by about 120 times more in the area of half non-periodic silver nano particle, compared to the areas of the silicon (Si) substrate.

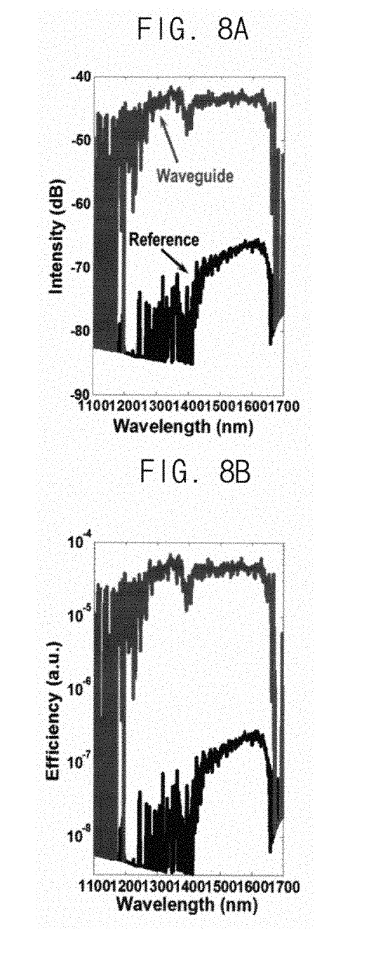

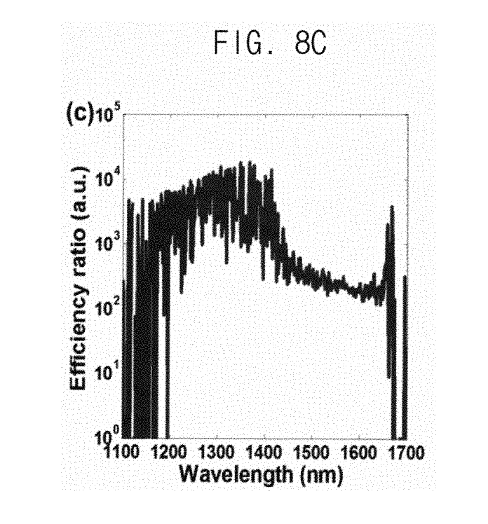

In FIG. 8A, the intensity of the signal transmitting through the optical waveguide including the half non-periodic silver nano particle arrangement is illustrated. Here, the intensity of the signal is for the short wavelength near infrared ray band measured with a fixed signal transmitting distance of 1 mm. The line illustrated at an upper portion is the intensity for the optical waveguide, and the line illustrated at a lower portion is the reference intensity, in FIG. 8A.

Referring to FIG. 8A, the intensity of the signal transmitting through the optical waveguide is much higher than that of the reference, by more than about 10,000 times.

In FIG. 8B, transmitting efficiency is calculated based on a mathematical method using the result of FIG. 8A.

In FIG. 8C, an efficiency ratio of the half non-periodic silver nano particle arrangement is calculated with respect to the silicon substrate.

Here, referring to FIGS. 8B and 8C, the efficiency of the signal transmitting in the half non-periodic silver nano particle arrangement is much higher than that of the reference, by more than about 10,000 times.

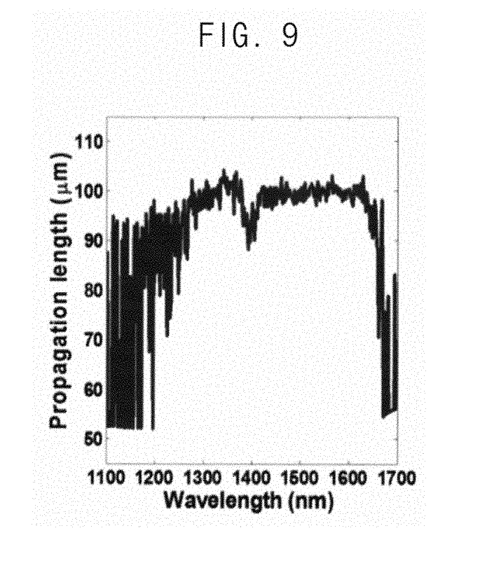

The signal transmitting distance (propagation length) of the optical waveguide according to the present example embodiment may be illustrated in FIG. 9.

Referring to FIG. 9, in the optical waveguide including the half non-periodic silver nano particle arrangement according to the present example embodiment, the signal transmitting distance may be enlarged to about 100 μm, compared to the conventional signal transmitting distance of about several micro-meters.

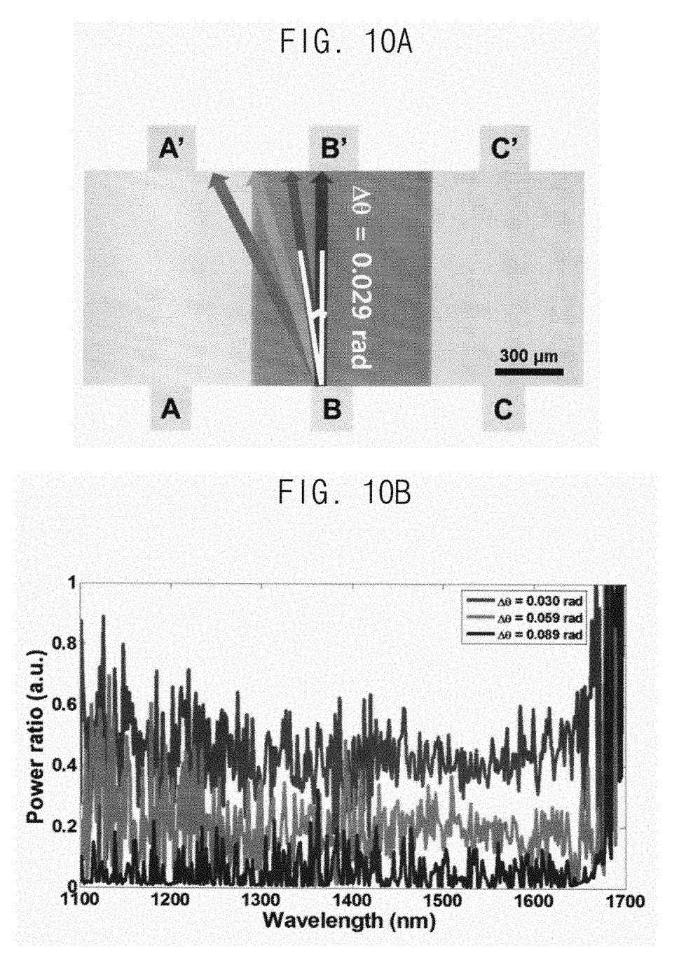

In FIG. 10A, a method for measuring a straightness of an optical wave for an incident near infrared ray is illustrated, for the optical waveguide including the half non-periodic silver nano particle arrangement according to the present example embodiment.

Referring to FIG. 10A, the light is incident to the optical waveguide including the half non-periodic silver nano particle arrangement (B), and then is deviated to the adjacent silicon substrate (A′), which means the change of the straightness.

For example, the relative position between the light and the optical fiber is controlled, such that 0.029 rad)(1.718° is deviated from an aligned axis by 1 mm, and then is repeated for the experimental.

Thus, FIG. 10B shows the signal transmitting efficiency decreasing relation according to a change of an optical wave angle with respect to the incident infrared ray, in the optical waveguide including the half non-periodic silver nano particle arrangement.

Referring to FIG. 10B, the signal transmitting efficiency is the largest when the straightness is maintained, and the signal transmitting efficiency is decreased as the straightness is changed. For example, as the deviated angle of the aligned axis is increased, the signal transmitting efficiency is decreased.

Accordingly, the optical waveguide including the half non-periodic silver nano particle arrangement, may transmit the signal with more increased intensity and more increased stability, and thus the signal transmitting efficiency may be increased.

According to the present example embodiments, metal nano particle arrangement having randomness may be performed with a relatively large size and a relatively simple process from a metal thin film, using solid dewetting.

Here, half-non periodic metal nano particle arrangement may be formed in addition to periodic metal nano particle arrangement at the same time, using the conventional photo lithographic process. Here, a thickness of the metal thin film, a temperature of heat treatment, a processing time, and so on may be controlled, to control a size or a distance between the metal nano particles effectively, so that metal nano particle arrangement may be properly formed.

By forming an optical waveguide as mentioned above, a loss of the near infrared ray broadband incident light may be minimized by a relatively long distance (maximum distance is about 120 μm along a direction parallel with the metal-dielectric intersurface (signal loss with respect to the near infrared ray light signal with a range of 1,200-1,600 nm is less than 3.8 dB 100 μm⁻1, such that the near infrared ray broadband incident light may be transmitted.

In addition, near infrared short wavelength incident signal which is used for a communication band may be stably transmitted along a surface.

In addition, a transmitting distance of near infrared broadband incident light which is used for a chemical sensor or a spectroscope may be differentiated or a transmitting efficiency thereof may be differentiate, so that the planer spectrum effect may be increased.

Having described the example embodiments of the present invention and its advantage, it is noted that various changes, substitutions and alterations can be made herein without departing from the spirit and scope of the invention as defined by appended claims.

What is claimed is:

1. A method for fabricating a broadband near infrared plasmonic waveguide, the method comprises:
forming a first pattern on a substrate;
evaporating a metal thin film on the substrate on which the first pattern is formed;
removing the first pattern from the substrate on which the metal thin film is evaporated, to remain a second pattern on the substrate on which the metal thin film is evaporated; and
heating the substrate on which the second pattern is formed, to induce dewetting, so that metal nano particles are formed on the substrate.

2. The method of claim 1, wherein the forming the first pattern on the substrate comprises:
coating a photoresist on the substrate;
hardening the photoresist coated on the substrate;
partially exposing the hardened photoresist firstly using a mask, to form the first pattern;
hardening the first pattern and the photoresist, with removing the mask;
exposing the first pattern and the photoresist secondly; and
removing the photoresist which is not exposed to a light from the substrate due to the mask in the exposing firstly.

3. The method of claim 2, wherein in the coating the photoresist on the substrate, a first solution and the photoresist are sequentially coated on the substrate, and then a spin coating is performed.

4. The method of claim 3, wherein the first solution is a methoxy-propyl acetate solution.

5. The method of claim 2, wherein between the coating the photoresist on the substrate and the hardening the photoresist, a side area of the coated photoresist is removed using acetone.

6. The method of claim 2, wherein in the forming the first pattern, UV light having a wavelength between about 350 nm and about 450 nm is used for the exposing.

7. The method of claim 2, wherein in the removing the photoresist from the substrate, the photoresist is removed from the substrate using a developing solution of tetramethylammonium hydroxide, and then the photoresist remained in the substrate is additionally removed using a deionized water.

8. The method of claim 1, wherein in the removing the first pattern, the first pattern is removed using an ultrasonic wave generator.

9. The method of claim 1, wherein the metal thin film is melted to be arranged non-periodically, so that the metal nano particles are formed.

10. The method of claim 9, wherein in the forming the metal nano particles, a heated tube electric furnace or a heated plate are used for the heating.

11. The method of claim 10, wherein sizes of the metal nano particles and distances between the metal nano particles, are controlled by a heating time, a thickness of the metal thin film and a surface state of the substrate.

12. The method of claim 1, wherein each of the metal nano particles has a radius less than about 300 nm.

13. The method of claim 1, wherein the metal thin film is formed from one of silver, gold, platinum, aluminum, iron, zinc, copper, tin, bronze, brass and nickel.
